(19) United States
(12) Patent Application Publication
(10) Pub. No.: US 2004/0208075 A1
(43) Pub. Date: Oct. 21, 2004

(54) Refresh clock generator

(76) Inventor: Yuan-Mou Su, Tainan County (TW)

Correspondence Address: BIRCH STEWART KOLASCH & BIRCH, PO BOX 747, FALLS CHURCH, VA, 22040-0747, US

(21) Appl. No.: 10/763,251

(22) Filed: Jan. 26, 2004

(30) Foreign Application Priority Data
Apr. 17, 2003 (TW) 92108888

(51) Int. Cl. G11C 7/00

(52) U.S. Cl. 365/222

(57) ABSTRACT

A method for generating refresh clock of a DRAM module, the DRAM module comprises a plurality of memory cells, and each memory cell comprises a storage capacitor. First, a dummy capacitor is provided, the dummy capacitor is positively correlated with the storage capacitor, and then a refresh clock is generated according to the dummy capacitor.

### BACKGROUND OF THE INVENTION

1. Field of the Invention

The invention relates to a method and apparatus for refreshing a dynamic random access memory (DRAM), and more particularly to a method and apparatus for refreshing DRAM according to environmental temperature.

2. Description of the Related Art

DRAM, the most commonly used solid state access memory chip provides many advantages, such as high density, low cost, and high operating speed among others. DRAM stores memory data by electric charge, however, and the electric charge gradually lost over time by the reverse bias voltage leakage current of the PN junction of the NMOS transistor in the DRAM memory cell. Hence, the DRAM module must be continuously updated, even in stand-by mode, to prevent data loss over time. The process of updating DRAM memory data is known as a refresh and the time elapsed between refresh processes is known as the refresh interval. A high frequency, or shorter, refresh interval is inefficient as it consumes excessive power.

Power management in primarily battery powered devices such as PDAs and cell phones, is particularly important as power must be consumed as conservatively as possible to prolong battery life

### SUMMARY OF THE INVENTION

The present invention is directed to generating an appropriate refresh interval to refresh DRAM, while reducing unnecessary power consumption.

Accordingly, the present invention provides a method for generating a refresh clock of a DRAM module. The DRAM module comprises a plurality of memory cells, and each memory cell comprises a storage capacitor. A dummy capacitor is provided, the dummy capacitor is positively correlated with the storage capacitor, and then a refresh clock is generated according to a capacitance of the dummy capacitor. A refresh interval of the refresh clock is generally positively correlated with the capacitance of the dummy capacitor.

Accordingly, the present invention provides a refresh clock generator. The DRAM module comprises a plurality of memory cells, and each memory cell comprises a storage capacitor. The refresh clock generator comprises a dummy capacitor and a clock generator. The dummy capacitor is positively correlated with the storage capacitor. The clock generator couples to the dummy capacitor to generate a refresh clock. A refresh interval of the refresh clock is generally positively correlated with the capacitance of the dummy capacitor.

Positive correlation indicates that the capacitance of the dummy capacitor is increased when the capacitance of the storage capacitor is increased.

When the storage capacitor of the DRAM module is modified, the refresh clock of the present invention is also modified. Therefore, memory cell data is maintained, and excessive power consumption is reduced.

### BRIEF DESCRIPTION OF THE DRAWINGS

For a better understanding of the present invention, reference is made to a detailed description to be read in conjunction with the accompanying drawings, in which:

FIG. 1 shows a refresh generator of the present invention.

FIG. 2 shows an embodiment of a ring oscillator of the present invention.

### DETAILED DESCRIPTION OF THE INVENTION

When the capacitance of a storage capacitor of a DRAM module memory cell increases, the electric charge is also increased in order to maintain data stored therein, thus, the refresh interval is extended. That is to say, the refresh interval is interrelated with the capacitance of the storage capacitor. Therefore, the refresh interval of the present invention is automatically modified according to the capacitance of the storage capacitor.

In semiconductor processing, when the storage capacitors of a memory array are formed, dummy capacitors are simultaneously formed in a peripheral circuit region. The storage capacitors and the dummy capacitors are affected by many factors, such as critical dimension shift or non-uniform deposition. The dummy capacitors are positively correlated with the storage capacitors. Furthermore, the unused storage capacitors can be used as dummy capacitors.

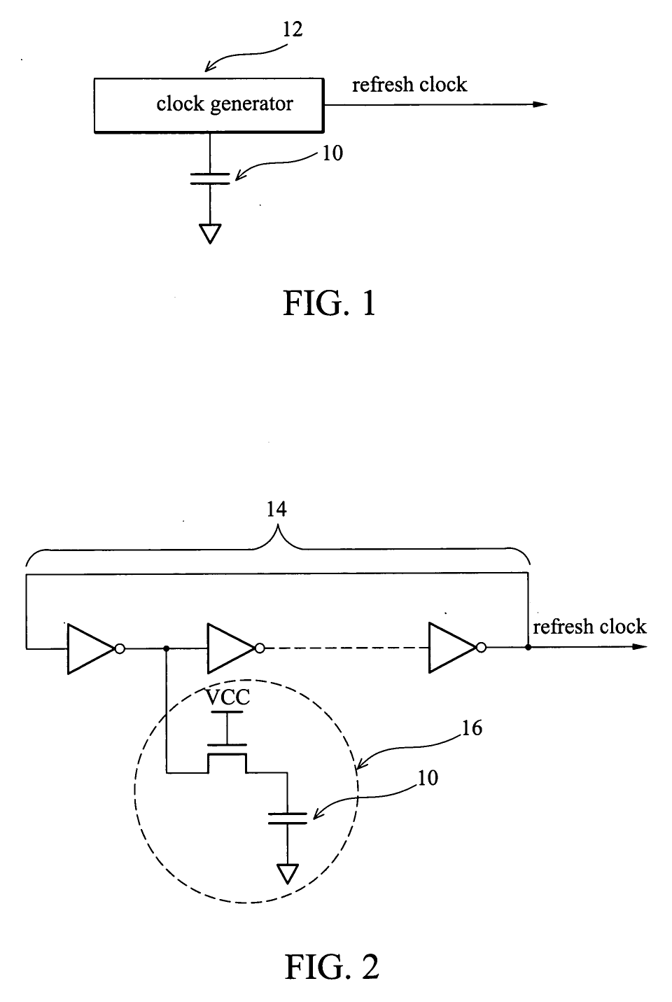

FIG. 1 shows a refresh generator of the present invention. The refresh clock generator comprises a dummy capacitor 10 and a clock generator 12. As described below, the dummy capacitors are positively correlated with the storage capacitors, clock intervals of the refresh clocks generated by the clock generator 12 increase when the capacitance of the dummy capacitor 10 increases.

FIG. 2 shows an embodiment of a ring oscillator of the present invention. The ring oscillator 14 comprises an odd number of inverters, and couples to at least one dummy cell 16 wherein the dummy cell 16 acts as a load. A gate of an NMOS transistor of the dummy memory cell 16 is turned on by coupling with a high potential (VCC). The dummy capacitor 10 of the dummy memory cell 16 acts as an inverter load, thus the refresh clock generated by the ring oscillator is affected by the dummy capacitor 10. The cycle of the refresh clock increases when the capacitance of the dummy capacitor increases, hence, the refresh interval is automatically adjusted with the capacitance of the dummy capacitor. In other words, the output terminal of each inverter has a dummy memory cell to modify the load from the inverter, and the refresh interval is subsequently modified.

The dummy memory cell 16 in FIG. 2 can be an unused memory cell of the memory array.

Compared with the invariable refresh interval of the conventional technique, the present invention provides the method and apparatus to generate a refresh clock with the capacitance of the storage capacitor, thus memory cell data is maintained, and power consumption is reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for generating a refresh clock of a DRAM module, wherein the DRAM module comprises a plurality of memory cells, each of the memory cells having a storage capacitor, comprising:
providing a dummy capacitor, the dummy capacitor has a positive correlation with the storage capacitor; and
generating a refresh clock according to a capacitance of the dummy capacitor;
wherein a refresh interval of the refresh clock is positively correlated with the capacitance of the dummy capacitor.

2. The method for generating a refresh clock of claim 1, further comprising a method for generating the refresh clock:
providing an oscillator for generating the refresh clock, wherein the dummy capacitor is an oscillator load.

3. The method for generating a refresh clock of claim 1, wherein the dummy capacitor is one of the storage capacitors.

4. A refresh clock generator of a DRAM module, wherein the DRAM module comprises a plurality of memory cells, each of the memory cells having a storage capacitor, comprising:
a dummy capacitor positively correlated with the storage capacitor; and
a clock generator for generating a refresh clock, and coupling to the dummy capacitor;
wherein a refresh interval of the refresh clock is positively correlated with a capacitance of the dummy capacitor.

5. The refresh clock generator of claim 4, wherein the clock generator is a ring oscillator and the dummy capacitor is a ring oscillator load.

6. The refresh clock generator of claim 5, wherein the refresh clock generator comprises a plurality of dummy capacitors, the ring oscillator comprises a plurality of inverters, and each output terminal of the inverters couples to a corresponding dummy capacitor.

7. The refresh clock generator of claim 4, wherein the dummy capacitor is one of the storage capacitors.
